(19) United States
(12) Patent Application Publication
(10) Pub. No.: US 2014/0063882 A1
(43) Pub. Date: Mar. 6, 2014

(54) Circuit Arrangement with Two Transistor Devices

(71) Applicants: Franz Hirler, Isen (DE); Anton Mauder, Kolbermoor (DE)

(72) Inventors: Franz Hirler, Isen (DE); Anton Mauder, Kolbermoor (DE)

(73) Assignee: INFINEON TECHNOLOGIES AUSTRIA AG, Villach (AT)

(21) Appl. No.: 13/598,755

(22) Filed: Aug. 30, 2012

(51) Int. Cl. H01L 27/06; H02M 7/217

(52) U.S. Cl. CPC H01L 27/0629; H02M 7/217
USPC 363/127; 257/299

(57) ABSTRACT

A circuit arrangement includes a first transistor device and a second transistor device. Each transistor device includes a first load terminal, a second load terminal, a gate terminal, and a control terminal. The first load terminals are electrically connected, and the control terminals are electrically connected. A capacitive storage element is connected between the first load terminals and the control terminals.

### TECHNICAL FIELD

Embodiments of the present invention relate to a circuit arrangement, in particular a circuit arrangement with two transistor devices that each have one of their load terminals connected to a common circuit node.

### BACKGROUND

Transistor devices, in particular power MOS transistor devices, are widely used in automotive, industrial and consumer electronic applications for switching electric loads, for rectification purposes or for power conversion purposes. A conventional power MOS transistor includes a source region, a body region, a drift region and a drain region, where the drift region is arranged between the body region and the drain region and where the body region separates the drift region from the source region. A gate electrode is adjacent the body region and dielectrically insulated from the body region. The gate electrode is operable to control a conducting channel in the body region between the source region and the drift region.

In a relatively new type of power MOS transistor device a drift control region extends along the drift region and is dielectrically insulated from the drift region by a dielectric layer. The drift control region serves to generate a conducting channel in the drift region along the dielectric layer when the transistor device is in an on-state. By means of the conducting channel, the on-resistance of the transistor device can be reduced compared to MOS transistor devices without drift control region. In this type of transistor device, the drift region needs to be charged in the on-state of the transistor device and needs to be discharged in the off-state. In order to keep losses low, electrical charges required to charge the drift control region are buffered in a capacitive storage element when the transistor device is in the off-state and are shifted from the capacitive storage element into the drift control region in the on-state.

The capacitive storage element may be integrated in the same semiconductor body (semiconductor chip) in which active device regions of the transistor device are integrated. However, integrated capacitive storage elements are chip space consuming.

### SUMMARY

A first embodiment relates to a circuit arrangement. The circuit arrangement includes a first transistor device and a second transistor device, each including a first load terminal, a second load terminal, a gate terminal, and a control terminal. The first load terminals are electrically connected, and the control terminals are electrically connected. The circuit arrangement further includes a capacitive storage element connected between the first load terminals and the control terminals.

A second embodiment relates to a rectifier circuit. The rectifier circuit includes a transistor device with a first load terminal, a second load terminal, a gate terminal, and a control terminal. The control terminal is coupled to a drift control region, and the control region is dielectrically insulated from a drift region by a drift control region dielectric. The rectifier circuit further includes a drive circuit. The drive circuit is configured to detect a polarity of a voltage between the first load terminal and the second load terminal and is configured to generate a drive signal received at the gate terminal of the transistor device dependent on the detected polarity.

A third embodiment relates to a rectifier circuit. The rectifier circuit includes a transistor device with a first load terminal, a second load terminal, and a gate terminal, and a drive circuit. The drive circuit is configured to detect a polarity of a voltage between the first load terminal and the second load terminal and is configured to generate a drive signal received at the gate terminal of the transistor device dependent on the detected polarity. The drive circuit includes a driver stage with an output coupled to the gate terminal of the transistor device, a first input coupled to the first load terminal of the transistor device, and a second input coupled to the second load terminal of the transistor device via a voltage limiting element.

### BRIEF DESCRIPTION OF THE DRAWINGS

Examples will now be explained with reference to the drawings. The drawings serve to illustrate the basic principle, so that only aspects necessary for understanding the basic principle are illustrated. The drawings are not to scale. In the drawings the same reference characters denote like features.

FIG. 1 illustrates a first embodiment of a circuit arrangement including a first transistor device, a second transistor device, and a capacitive storage element;

FIG. 2 illustrates a vertical cross sectional view of one of the first and second transistor devices according to a first embodiment;

FIG. 3 illustrates a vertical cross sectional view of one of the first and second transistor devices according to a second embodiment;

FIG. 4 Illustrates a horizontal cross sectional view one of the first and second transistor devices according to a first embodiment;

FIG. 5 Illustrates a horizontal cross sectional view one of the first and second transistor devices according to a second embodiment;

FIG. 6 illustrates a further vertical cross sectional view of the transistor device of FIG. 3;

FIG. 7 illustrates vertical cross sectional views of the first transistor device and the second transistor device and of capacitive storage cells of the capacitive storage elements;

FIG. 8 illustrates a circuit arrangement with two transistor devices implemented as a full-bridge circuit;

FIG. 9 illustrates a circuit arrangement with two transistor devices implemented as a rectifier circuit;

FIG. 10 illustrates a first embodiment of a charging circuit coupled to the capacitive storage element;

FIG. 11 illustrates a second embodiment of a charging circuit coupled to the capacitive storage element;

FIG. 12 illustrates the two transistor devices in the rectifier circuit of FIG. 9 and an embodiment of a drive circuit for the two transistor devices;

FIG. 13 illustrates a first embodiment of rectifier circuit including one transistor device and a drive circuit for the transistor device;

FIG. 14 illustrates a second embodiment of rectifier circuit including one transistor device and a drive circuit for the transistor device;

FIG. 15 illustrates a third embodiment of rectifier circuit including one transistor device and a drive circuit for the transistor device; and

FIG. 16 illustrates a vertical cross sectional view of a superjunction transistor device.

### DETAILED DESCRIPTION

In the following Detailed Description, reference is made to the accompanying drawings, which form a part thereof, and in which is shown by way of illustration specific embodiments in which the invention may be practiced.

FIG. 1 illustrates a first embodiment of a circuit arrangement with a first transistor device 10₁ and a second transistor device 10₂. Each of the first and second transistor devices 10₁, 10₂ includes a first load terminal S₁, S₂, a second load terminal D₁, D₂, a gate terminal G₁, G₂, and a control terminal C₁, C₂. The first load terminals S₁, S₂ are connected. In FIG. 1, reference character S₁₂ denotes a circuit node common to the first load terminals S₁, S₂. This circuit node will be referred to as common (first) load terminal in the following. Further, the control terminals C₁, C₂ of the first and second transistor devices 10₁, 10₂ are connected. In FIG. 1, reference character C₁₂ denotes a circuit node common to the control terminals C₁, C₂. This circuit node will be referred to as common control terminal in the following.

Referring to FIG. 1, a capacitive storage element 40, such as a capacitor, is connected between the common control terminal C₁₂ and the common load terminal S₁₂. That is, that the capacitive storage element 40 has one terminal connected to the control terminals C₁, C₂ of the first and second transistor devices 10₁, 10₂, and has another terminal connected to the first load terminals S₁, S₂ of the first and second transistor devices 10₁, 10₂.

The first and second transistor devices 10₁, 10₂ of FIG. 1 are MOSFETs. Each of these MOSFETs can be switched on and switched off by applying a suitable drive signal DR₁, DR₂ to the corresponding gate terminal G₁, G₂. A drive circuit for generating the drive signals DR₁, DR₂ is not illustrated in FIG. 1. In the MOSFETs of FIG. 1, the first load terminals S₁, S₂ are source terminals, and the second load terminals D₁, D₂ are drain terminals. The MOSFETs can be implemented as n-type MOSFETs or as p-type MOSFETs. Further, the MOSFETs can be implemented as enhancement MOSFETs or as depletion MOSFETs. Just for illustration purposes, the circuit symbols of the MOSFETs 10₁, 10₂ of FIG. 1 are circuit symbols of n-type enhancement MOSFETs. An n-type enhancement MOSFET has a positive threshold voltage and switches on when the drive signal (the gate-source voltage) is above the threshold voltage, while an n-type enhancement MOSFET switches off when the drive signal is below the threshold voltage. An n-type depletion MOSFET has a negative threshold voltage.

Each of the MOSFETs 10₁, 10₂ of FIG. 1 has an internal drift region that is explained in further detail herein below. Via the control terminal C₁, C₂ of each of the MOSFETs 10₁, 10₂ a conducting channel (accumulation channel or inversion channel) can be generated in the drift region in order to reduce the on-resistance of the corresponding MOSFET 10₁, 10₂. When one MOSFET is in the on-state and a conducting channel in the drift region is to be generated, electrical charges need to be provided to the control terminal C₁, C₂ of the corresponding MOSFET 10₁, 10₂. These electrical charges can be stored in the capacitive storage element 40 when the MOSFET is in the off-state. In the circuit arrangement of FIG. 1, the two MOSFETs 10₁, 10₂ share the capacitive storage element 40. The capacitance of the capacitive storage element 40 shared by the two MOSFETs 10₁, 10₂ can be lower than the overall capacitance of two individual capacitive storage elements, with each of these individual capacitive storage elements assigned to only one of the MOSFETs.

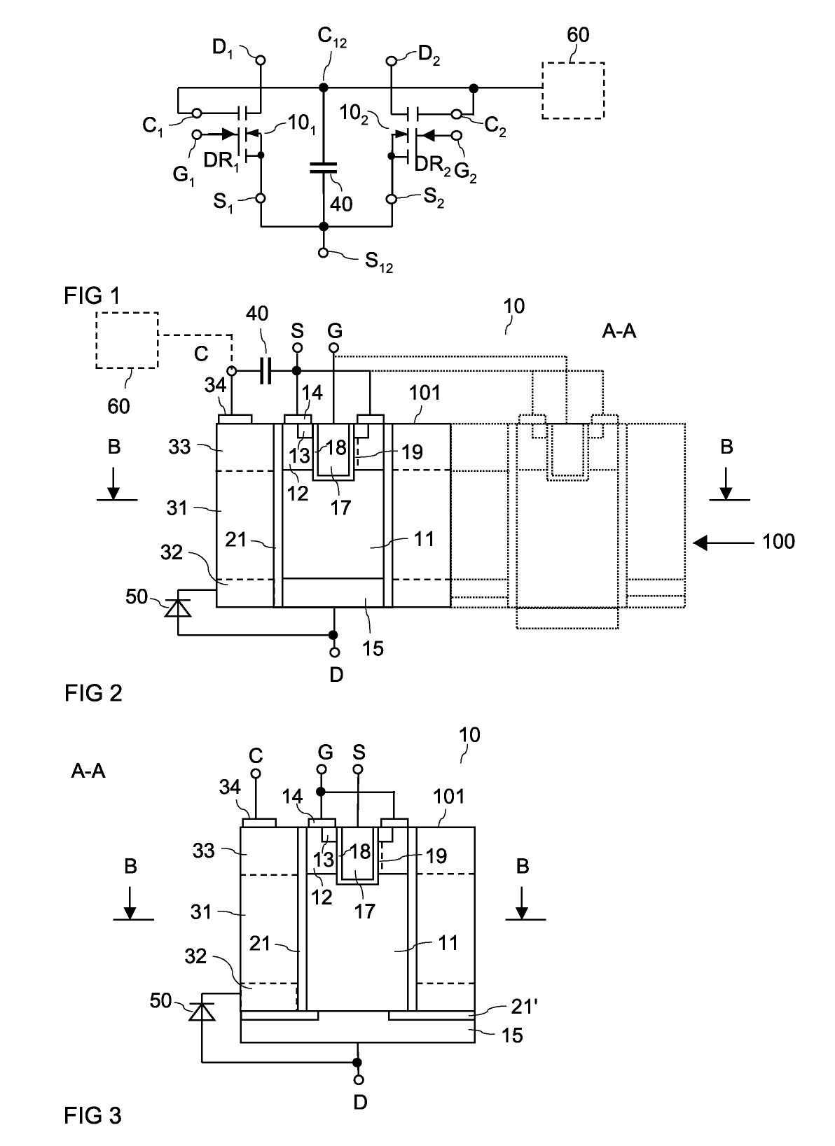

In order to ease understanding the operating principle of each of the MOSFETs 10₁, 10₂, FIG. 2 schematically illustrates a vertical cross sectional view of one of the MOSFETs 10₁, 10₂. Each of the first and second transistor devices 10₁, 10₂ may be implemented as illustrated in FIG. 2. In FIG. 2, reference character 10 denotes the transistor device, G denotes the gate terminal, S denotes the first load terminal (source terminal), D denotes the second load terminal (drain terminal), and C denotes the control terminal of the transistor device 10.

The transistor device 10 of FIG. 2 is implemented as a MOSFET, specifically as a vertical MOSFET. A vertical MOSFET is a MOSFET in which a current flow direction corresponds to a vertical direction of a semiconductor body 100 in which active device regions of the MOSFET are implemented. The “vertical direction” of the semiconductor body 100 is a direction perpendicular to a first surface 101 of the semiconductor body 100. FIG. 2 shows a vertical cross sectional view of the MOSFET, or, more precisely, a vertical cross sectional view of the semiconductor body 100. The basic operating principle explained in the following, however, is not restricted to a vertical MOSFET, but also applies to a lateral MOSFET in which a current flow direction corresponds to a lateral direction of a semiconductor body.

Referring to FIG. 2, the MOSFET includes a drift region 11, a body region 12, a source region 13, and a drain region 15. The source and drain regions 13, 15 are arranged distant in the current flow direction, which is the vertical direction of the semiconductor body 100 in the present embodiment. The body region 12 is arranged between the source region 13 and the drift region 12, and the drift region 11 is arranged between the body region 12 and the drain region 15. The drain region 15 is electrically connected to the drain terminal D (only schematically illustrated in FIG. 1). The source region 13 and the body region 12 are electrically connected to a source electrode 14 which forms or which is connected to the source terminal S.

The drift region 11, the body region 12, the source region 13, and the drain region 15 form active device regions of the MOSFET and are implemented in the semiconductor body 100. The active device regions are monocrystalline semiconductor regions according to one embodiment. The source electrode 14 may include a polycrystalline semiconductor material, a silicide or a metal.

The MOSFET further includes a gate electrode 17 adjacent the body region 12 and dielectrically insulated from the body region 12. In the embodiment of FIG. 2, the gate electrode 17 is arranged in a trench and extends from the source region 13 through the body region 12 to or into the drift region 11. The gate electrode 17 is dielectrically insulated from these semiconductor regions by a gate dielectric 18 and is connected to the gate terminal G. The gate dielectric 18 can be a conventional gate dielectric and includes, for example, an oxide, a nitride, or a high-k dielectric.

The MOSFET 10 of FIG. 2 is not restricted to be implemented with the gate electrode 17 in a trench. The MOSFET could also be implemented with a conventional planar gate electrode that is arranged above the first surface 101.

Referring to the explanation above, the MOSFET can be implemented as an n-type MOSFET or as a p-type MOSFET. In an n-type MOSFET, the source region 13 and the drain region 15 are n-doped, while the body region 12 is p-doped. In a p-type MOSFET, the source region 13 and the drain region 15 are p-doped while the body region 12 is n-doped. The doping concentration of the source region 13 and the drain region 15 is, for example in the range of between 5E17 cm⁻³ and 1E21 cm⁻³. The doping concentration of the body region 12 is, for example, in the range of between 5E16 cm⁻³ and 5E18 cm⁻³. The doping concentration of the drift region 11 is, for example, in the range of between 1E12 cm⁻³ and 1E15 cm⁻³.

Further, the MOSFET can be implemented as an enhancement (normally-off) MOSFET or as a depletion (normally-on) MOSFET. In an enhancement MOSFET, the body region 12, that is complementary to the source region 13, extends to the gate dielectric 18. In a depletion MOSFET, the body region 12 at least along the gate dielectric 18 includes a channel region 19 (illustrated in dashed lines along one side of the gate electrode 17 in FIG. 1) of the same doping type as the source region 13.

In the type of MOSFET illustrated in FIG. 2, the drift region 11 can have the same doping type as the source region 13 and the drain region 15, or can be doped complementarily to the source region 13 and the drain region 15. In the latter case, at least one section of the drift region 11 between a dielectric layer 21 which will be explained in the following and a channel region of the MOSFET may have the same doping type as the source region 13. The “channel region” of the MOSFET is a region of the body region 13 along the gate dielectric 18 where the gate electrode 17 controls a conducting channel.

Referring to FIG. 2, the MOSFET further includes a drift control region 31 that is dielectrically insulated from the drift region 11 by a dielectric layer 21. The dielectric layer 21 will be referred to as drift control region dielectric 21 in the following. The drift control region dielectric 21 extends in the current flow direction. Thus, in the embodiment illustrated in FIG. 2, the drift control region dielectric 21 is a vertical dielectric layer extending in the vertical direction of the semiconductor body 100. The drift control region 31 is configured to generate a conducting channel in the drift region 11 along the drift control region dielectric 21 when the MOSFET is in an on-state. This conducting channel helps to reduce the on-resistance of the MOSFET. The MOSFET, like a conventional MOSFET, is in the on-state, when an electrical potential is applied to the gate terminal G that induces a conducting channel in the body region 12 between the source region 13 and the drift region 11 along the gate dielectric 18, and when an electrical voltage is applied between the drain and the source terminals D, S. For example, in an n-type enhancement MOSFET, the voltage to be applied between the gate terminal G and the source terminal S is a positive voltage higher than a threshold voltage of the MOSFET. The conducting channel along the gate control region dielectric 21 is an accumulation channel when the drift region 11 has the same doping type as the source and drain regions 13, 15, and the conducting channel is an inversion channel, when the drift region 11 is doped complementarily to the source and drain regions 13, 15.

Referring to FIG. 1, the circuit arrangement further includes a charging source (biasing source) 60 coupled to the common control terminal C₁₂. The biasing source 60 is also illustrated in FIG. 2.

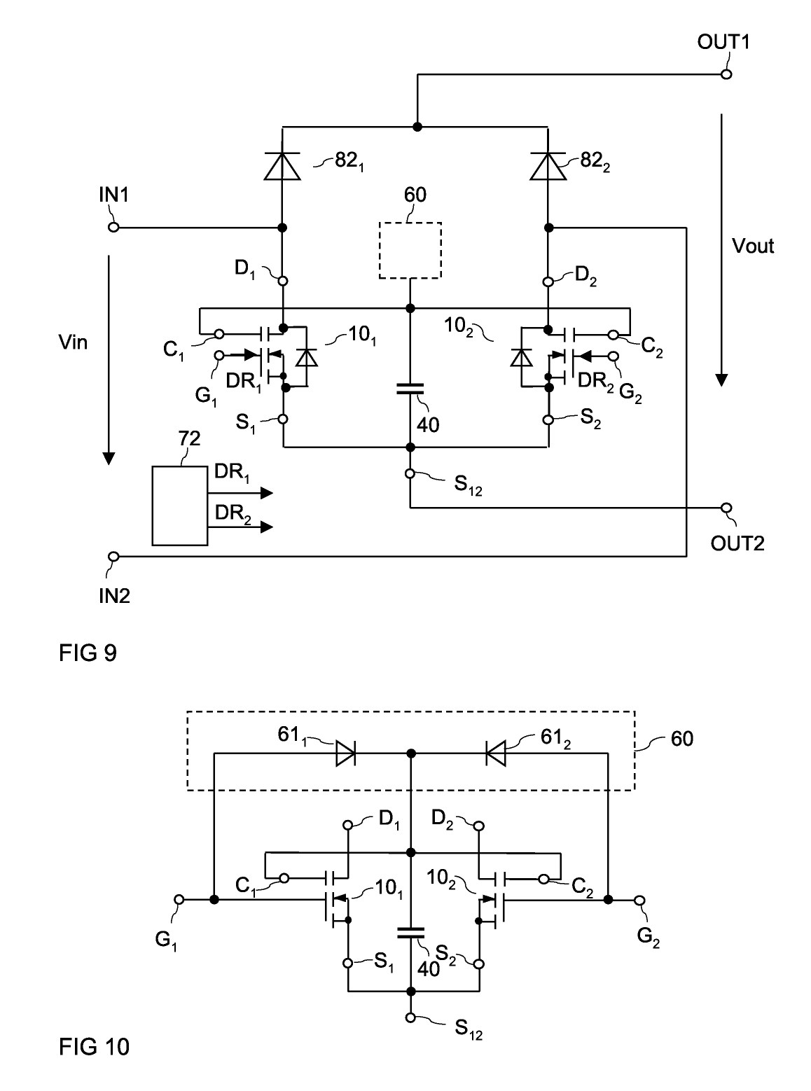

The biasing source 60 is configured to bias the drift control region 31 such that a conducting channel is generated in the drift region 11 along the gate control region dielectric 21 when the MOSFET is in the on-state. In an arrangement with an n-type MOSFET, the biasing source 60 is configured to charge the drift control region 31 such that the drift control region 31 assumes an electrical potential higher than the electrical potential of the drift region 11, when the MOSFET is in an on-state. In this case, an electron channel (as an accumulation or an inversion channel, dependent on the doping type of the drift region 11) is generated in the drift region 11 along the drift control region dielectric 21. In an arrangement with a p-type MOSFET, the biasing source 60 is configured to charge the drift control region 31 such that the drift control region 31 assumes an electrical potential lower than the electrical potential of the drift region 11. In this case, a hole channel is generated along the drift control region dielectric 21. The biasing source 60 can be implemented in many different ways. Two possible embodiments are explained with reference to FIGS. 8 and 9 herein below.

Referring to FIG. 1, the capacitive storage element 40 is connected between the control terminal C₁, C₂ of each of the first and second transistor devices 10₁, 10₂ and the first load terminal S₁, S₂ of each of the first and second transistor devices 10₁, 10₂. This capacitive storage element 40 is also illustrated in FIG. 2. Referring to FIG. 2, the capacitive storage element 40 is coupled between the drift control region 31 and the source terminal S. In the off-state of the MOSFET, the capacitive storage element 40 serves to store charge carriers from the drift control region 31. In the on-state, these charge carriers are needed in the drift control region 31 for controlling (generating) the conducting channel in the drift region 11 along the drift control region dielectric 21. This is explained in further detail below. Storing charges from the drift region 31 in the capacitive storage element 40 during off-periods of the MOSFET and providing these charges from the capacitive storage element 40 to the drift region 31 when the MOSFET is switched on helps to reduce switching losses. The reduction of switching losses is, in particular, an issue at high switching frequencies.

Further, the MOSFET 10 may include a rectifier element 50, such as a diode, connected between the drain region 15 and a drain-sided end of the drift control region 31. The drift control region 31 extends along the drift region in a current flow direction of the MOSFET. The “drain-sided end” of the drift control region 31 is the end that is located towards the drain region 15 (or drain electrode 16) of the MOSFET. Consequently, a “source-sided end” of the drift control region 31 is the end that is located towards the source region 13 (or source electrode 14) of the MOSFET. Optionally, the rectifier element 50 is connected to a connection region 32 which has the same doping type as the source and drain regions 13, 15, so that the connection region 32 is n-doped in an n-type MOSFET and p-doped in a p-type MOSFET. The connection region 32 has a higher doping concentration than the drift control region 31. The doping concentration of the connection region 32 is, for example, in the range of between 10E18 cm⁻³ and 10E21 cm⁻³.

The MOSFET 10 may further include a semiconductor region 33 doped complementarily to the source and drain regions 13, 15 of the MOSFET and adjoining the drift control region 31 at a source-sided end of the drift control region 31. In an n-type MOSFET the semiconductor zone 33 is p-doped, and in a p-type MOSFET the semiconductor zone 33 is n-doped. The biasing source 60 is connected to the drift control region 31 via this optional semiconductor region 33. Referring to FIG. 2, the biasing source 60 can be connected to a contact electrode 34, with the contact electrode 34 being connected to the drift control region 31 or the optional semiconductor region 33, respectively. For electrically connecting the drift control region 31 or the optional semiconductor region 33 to the contact electrode 34, the drift control region 31 or the optional semiconductor region 33, respectively, may include a more highly doped contact region (not illustrated) of the same the doping type as the drift control region 31 or the optional semiconductor region 33, respectively. This contact region is contacted by the contact electrode 34.

The doping concentration of the drift control region 31 may correspond to the doping concentration of the drift region 11. The doping type of the drift control region 31 may correspond to the doping type of the drift region 11, or may be complementary to the doping type of the drift region 11. According to one embodiment, the drift control region 31 and the drift region 11 are intrinsic.

The basic operating principle of the MOSFET of FIG. 2 is now explained. For explanation purposes it is assumed that the MOSFET is an n-type enhancement MOSFET with an n-doped drift region 11, and that the drift control region 31 has the same doping type as the drift region 11. In this case, the biasing source 60 is configured to bias the drift control region 31 to have a positive potential relative to the electrical potential of the source terminal S (source potential), when the MOSFET is in the on-state. The MOSFET is in the on-state, when the drive potential applied to the gate terminal G generates a conducting channel in the body region 12 between the source region 13 and the drift region 11. In the on-state, the drift control region 31, which has a higher electrical potential than the drift region 11, generates an accumulation channel in the drift region 11 along the drift control region dielectric 21. This accumulation channel significantly reduces the on-resistance of the MOSFET as compared to a MOSFET without a drift control region. When the drift region 11 is doped complementarily to the source and drain regions 13, 15, the drift control region 31 generates an inversion channel in the drift region 11 along the drift control region dielectric 21.

The MOSFET is in the off-state, when the channel along the gate dielectric 18 in the body region 12 is interrupted. In this case, a depletion region expands in the drift region 11 beginning at a pn-junction between the body region 12 and the drift region 11. The depletion region expanding in the drift region 11 causes a depletion region also to expand in the drift control region 31, which, like the drift region 11, may include a monocrystalline semiconductor material. By virtue of a depletion region expanding in the drift region 11 and a depletion region expanding in the drift control region 31, a voltage across the drift control region dielectric 21 is limited.

In the off-state of the MOSFET, the capacitive storage element 40 serves to store electrical charges that are required in the drift control region 31 when the MOSFET is in its on-state. These charges are positive charges in an n-type MOSFET and can be provided by the optional semiconductor region 33. The capacitive storage element 40 may be integrated partially or completely in the drift control region 31 or the optional semiconductor region 33. This is explained in greater detail with reference to FIG. 5 below.

The rectifier element 50 allows charge carriers that are thermally generated in the drift control region 31 to flow to the drain region 15, in order to prevent an electrical potential of the drift control region 31 to increase in an uncontrolled manner. The rectifier element 50 therefore operates as a voltage limiting element that limits a voltage difference between the electrical potential of the drift control region 31 and the drain region 15. The rectifier element 50 is connected up such that in the on-state of the MOSFET the drift control region 31 may assume a higher electrical potential than the potential at the drain terminal D.

The MOSFET can be implemented with a cell-like structure and may include a plurality of transistor cells connected in parallel. Each transistor cell includes a source region 13, a body region 12, a drift region 11, a drain region 15, a gate electrode 17, a gate dielectric 18, a drift control region dielectric 21 and a drift control region 31, where each of these device regions may be shared by two or more transistor cells. In FIG. 2, two transistor cells are illustrated in solid lines, with these two transistor cells having one gate electrode 17 and one drift region 11 in common. Further transistor cells are illustrated in dotted lines in FIG. 2. The individual transistor cells are connected in parallel by having their source regions 13 connected to a common source terminal S, by having their drain regions 15 connected to a common drain terminal D, and by having their gate electrodes 17 connected to a common gate terminal G.

FIG. 3 illustrates a vertical cross sectional view of a MOSFET 10 in which the drain region 15 does not only adjoin the drift region 11, but is also adjacent the drift control region 31 at the drain-sided end of the MOSFET. At the drain-sided end, a dielectric layer 21′ is arranged between the drift control region 31 (or the optional region 32) and the drain region 15 and dielectrically insulates the drift control region 31 from the drain region 15 in this region of the MOSFET. The other features of the MOSFET 10 of FIG. 3 correspond to those of FIG. 2 to which reference is made.

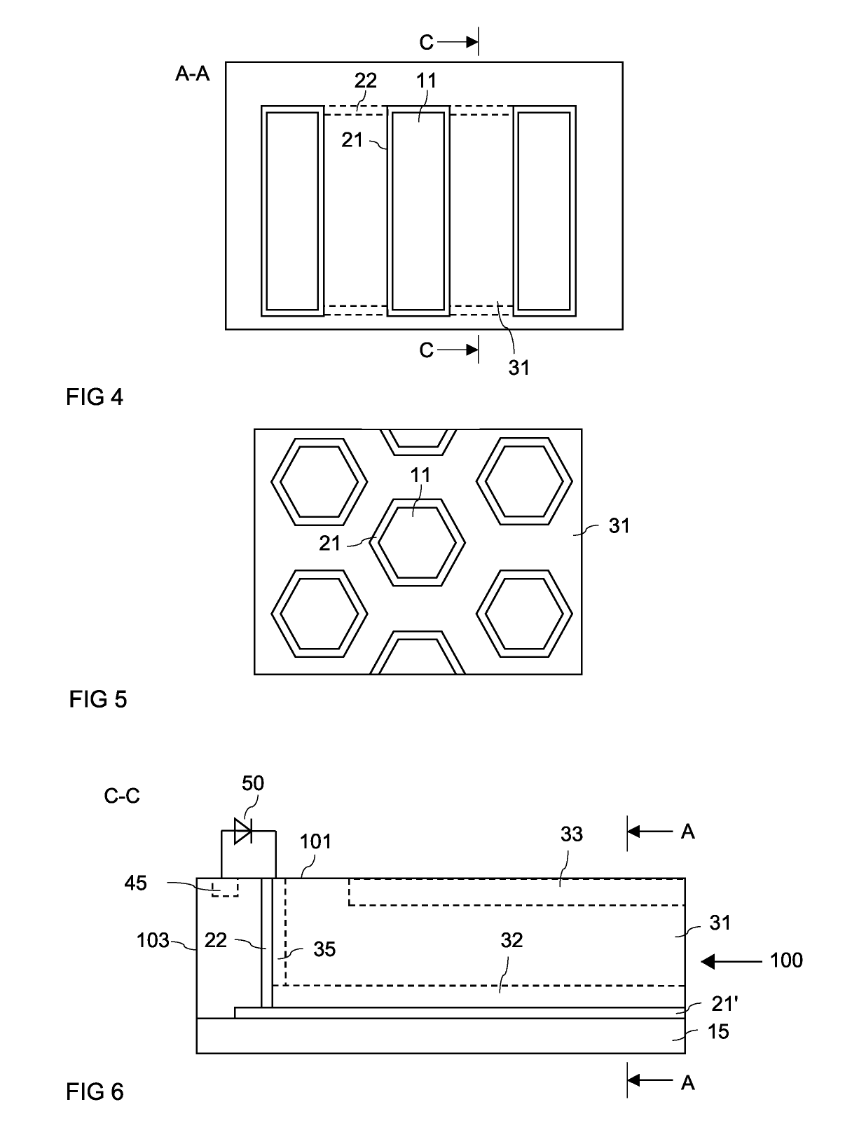

FIGS. 4 and 5 each show horizontal cross sectional views of the MOSFET of FIG. 2 or FIG. 3 in a horizontal section plane B-B that goes through the drift region 11 and the drift control region 31.

Referring to FIG. 4, the drift regions 11 of the individual transistor cells may have a longitudinal (stripe or elongated) shape in the horizontal plane. One drift control region 31 may surround the individual drift regions 11. According to a further embodiment (illustrated in dashed lines in FIG. 4) there is a plurality of drift control regions 31 having a longitudinal shape, with each drift control region 31 being terminated by further dielectric layers 22 at the longitudinal ends.

Referring to FIG. 5, the drift regions 11 of the individual transistor cells may have a hexagonal shape. However, the drift regions 11 could also be implemented with other shapes, such as elliptical, rectangular, octagonal, or other polygonal shapes as well.

FIG. 6 shows a vertical cross sectional view of a MOSFET with longitudinal drift control regions 31 in a section plane C-C that goes through the drift control region 31. Referring to FIG. 6, the rectifier element 50 can be connected to the drift control region 31 at the first surface 101. In the embodiment of FIG. 6, the drain region 15 is also arranged below the drift control region 31 but is dielectrically insulated from the drift control region 31 by the further dielectric layer 21′. Thus, the drift control region 31 is arranged in a “dielectric well” that includes the drift control region dielectric 21 (not illustrated in FIG. 6), the dielectric 22 at the longitudinal ends (where in FIG. 6 only one longitudinal end is illustrated) and the further dielectric layer 21′ at the bottom of the drift control region dielectric. The rectifier element 50 is connected between the drain region 15 and a further connection zone 35. The further connection zone 35 has the same doping type as the connection zone 32 and extends from the first surface 101 along the dielectric layer 22 at the longitudinal end to the connection zone 32, so as to connect the rectifier element to the connection zone 32 at the drain-sided end of the MOSFET. The optional semiconductor region 33 is distant to the vertical connection region 35.

Referring to FIG. 6, the rectifier element 50 is connected between a contact region 45 at the first surface 101 and the vertical connection zone 35. The contact region 45 is located in an edge region of the semiconductor body 100. The edge region of the semiconductor body 100 is a region adjoining a vertical edge 103 of the semiconductor body 100. The vertical edge 103 terminates the semiconductor body 100 in a horizontal direction. In this embodiment, the further dielectric layer 23 does not extend to the vertical edge 103. Thus, the drain region 15 is in contact with the edge region in which the contact region 45 is located and is electrically connected to the diode 50 via the edge region and the contact region 45.

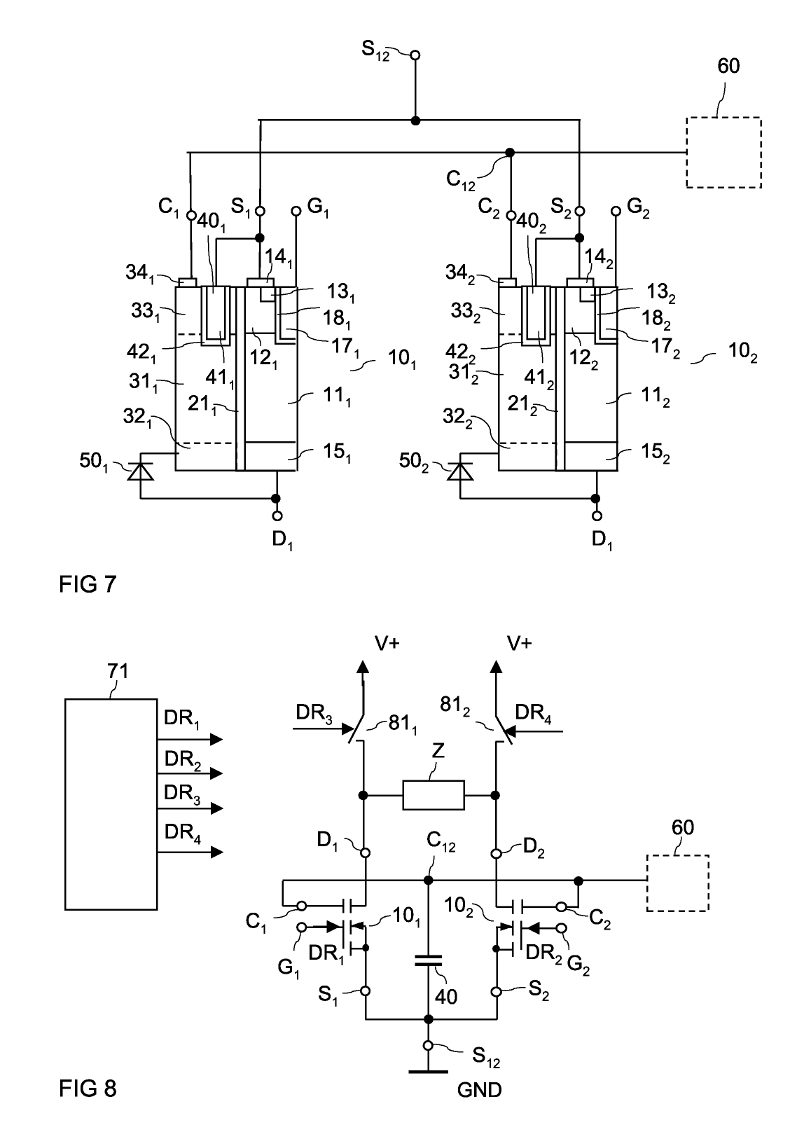

FIG. 7 schematically illustrates a vertical cross sectional view of one transistor cell of the first transistor device 10₁ and of one transistor cell of the second transistor device 10₂. Just for illustration purposes, each of these two transistor cells is implemented as explained with reference to FIG. 2. However, this is only an example. Other implementations of the transistor cells are also possible. Further, it is even possible to implement the transistor cells of the first transistor device 10₁ and the transistor cells of the second transistor device 10₂ mutually different. In FIG. 7, only one transistor cell of each of the first and second transistor devices 10₁, 10₂ is illustrated. However, referring to the explanation above, each of these transistor devices 10₁, 10₂ may be implemented with a plurality of transistor cells connected in parallel.

In FIG. 7, corresponding device regions in the first and second transistor devices 10₁, 10₂ have the same reference character, with the device regions of the first transistor device 10₁ additionally having a subscript index “1”, while the reference characters of the second transistor device 10₂ additionally having a subscript index “2”.

The active device regions of each of the first and second transistor devices 10₁, 10₂ are integrated in a semiconductor body. These active device regions are source regions 13₁, 13₂, body regions 12₁, 12₂, drift regions 11₁, 11₂, drain regions 15₁, 15₂ and drift control regions 31₁, 31₂. According to one embodiment, the active device regions of the first and second transistor devices 10₁, 10₂ are integrated in one common semiconductor body. According to a further embodiment, the active device regions of the first and second transistor devices 10₁, 10₂ are integrated into two separate semiconductor bodies.

According to one embodiment, the capacitive storage element includes a plurality of storage cells connected in parallel. Two of these storage cells are illustrated in FIG. 7, namely a first storage cell 40₁ integrated in the drift control region 31₁ of the first transistor device 10₁, and a second storage cell 40₂ integrated in the drift control region 31₂ of the second transistor device 10₂. Each of the storage cells 40₁, 40₂ illustrated in FIG. 7 is implemented as a capacitor and includes a first capacitor electrode 41₁, 41₂ connected to the common first load terminal (the common source terminal) S₁₂, a capacitor dielectric 42₁, 42₂, adjoining the capacitor electrode 41₁, 41₂ and a second capacitor electrode. The second capacitor electrode is formed by the drift control region 31₁, 31₂ and/or the connection region 33₁, 33₂, respectively.

In the embodiment illustrated in FIG. 7, one storage cell 40₁, 40₂ is integrated in each drift control region 31₁, 31₂. However, this is only an example. It is also possible, to implement more than one storage cell in each drift control region 31₁, 31₂. Further, dependent on a desired overall capacitance of the capacitive storage element 40, it is also possible to integrate storage cells in only some of the drift control regions 31₁, 31₂ of the individual transistor devices 10₁, 10₂. Implementing the storage cells in the drift control region 31₁, 31₂ is only an example. It is also possible, to implement the storage cells in other regions of the transistor devices 10₁, 10₂.

Referring to the explanation above, the capacitive storage element 40 stores charges that are required in the drift control region 31₁, 31₂ to generate a conducting channel in the drift region 11₁, 11₂ of one transistor device. In particular, in circuit applications in which the first and second transistor devices 10₁, 10₂ are switched on and off alternatingly, the capacitance of the capacitive storage element 40 can be lower than the overall capacitance of corresponding capacitive storage elements of two independent transistor devices. Thus, integration of the capacitive storage element 40 of FIG. 1 requires less chip space. Dependent on the specific application where the circuit with the two transistor devices 10₁, 10₂ is implemented the capacitive storage element 40 may be designed to have a very small capacitance, such as a capacitance of approximately zero. This, in particular, applies to applications in which the first and second transistor devices 10₁, 10₂ are switched on an off alternatingly. In this case, charge carriers from the drift control region of the transistor device that is about to be switched off are transferred to the transistor device that is about to be switched on, so that at most a small amount of electrical charge needs to be stored in the capacitive storage element.

Referring to FIG. 2, the drift control region dielectric 21, the body region 12 and the drift control region 31 or the optional semiconductor region 33 form a capacitive storage element between the source terminal 14 (that is connected to the body region 12 and the drift control region 31). This capacitive storage element may be sufficient in those cases in which a small capacitance is required and may form the capacitive storage element 40 explained before. In other cases, a capacitive storage element additional to the capacitive storage element formed through a section of the drift control region dielectric 21 may be formed. This additional capacitive storage element, like the capacitive storage element explained with reference to FIG. 7, has a capacitor dielectric other than the drift control region dielectric 21.

There are a plurality of different circuit applications that include two transistor devices that have a common load terminal and that may be switched on and off alternatingly.

A first embodiment of a circuit application that includes two transistor devices 10₁, 10₂ as explained with reference to FIG. 1, is illustrated in FIG. 8. The circuit of FIG. 8 is implemented as a full-bridge with two half-bridges. Each of the half-bridges includes one of the first and second transistor devices 10₁, 10₂ and a switch 81₁, 81₂ connected in series with the respective transistor device 10₁, 10₂. Each of these series circuits with one transistor device 10₁, 10₂ and a switch 81₁, 81₂ is connected between a terminal for a positive supply potential V+ and a terminal for a negative supply potential or reference potential GND, respectively. In the embodiment of FIG. 8, the common first load terminal S is connected to the terminal for the reference potential GND.

Each of the half-bridges includes an output. In the embodiment of FIG. 8, the output of each of the half-bridges is formed by the second load terminal (drain terminal) D₁, D₂ of one transistor device 10₁, 10₂. A load Z is connected between the outputs of the half-bridges. The load Z may be a conventional load. According to one embodiment, the load Z is an inductive load, such as a magnetic valve, a motor, or the like.

Referring to FIG. 8, the circuit arrangement with the full-bridge further includes a drive circuit 71. The drive circuit 71 is configured to generate drive signals DR₁, DR₂, DR₃, DR₄ for the transistor devices 10₁, 10₂ and the switches 81₁, 81₂ in accordance with a desired drive scheme. The drive scheme is dependent on the type of load Z driven by the full-bridge.

FIG. 9 illustrates a further embodiment of a circuit arrangement that includes a circuit with two transistor devices 10₁, 10₂ in accordance with FIG. 1. The circuit arrangement of FIG. 9 is implemented as a bridge-rectifier with four rectifier elements. Two of these rectifier elements are the first and second transistor devices 10₁, 10₂. Each of these transistor devices includes an integrated diode (body diode). The circuit symbol of this body diode is also illustrated in FIG. 9.

Referring to FIG. 9, the circuit arrangement includes input terminals IN1, IN2 for applying an input voltage Vin, and output terminals OUT1, OUT2 for providing a rectified output voltage Vout. Each of the rectifier elements of the bridge-rectifier is connected between one input terminal and one output terminal. In the embodiment of FIG. 9, the first transistor device 10₁ is connected between the first input terminal IN1 and the second output terminal OUT2, and the second transistor device 10₂ is connected between the second input terminal IN2 and the second output terminal OUT2. These transistor devices are connected such that the common second load terminal S₁₂ is connected to the second output terminal OUT2. In the embodiment of FIG. 9, the transistor devices 10₁, 10₂ are implemented as n-type transistors and anodes of the integrated body diodes are connected to the second output terminal OUT2.

Referring to FIG. 9, a third rectifier element 82₁ is connected between the first input terminal IN1 and the first output terminal OUT1, and a fourth rectifier element 82₂ is connected between the second input terminal IN2 and the first output terminal OUT1. These rectifier elements 82₁, 82₂ are implemented as diodes in the embodiment of FIG. 9 and have their cathode terminals connected to the first output terminal OUT1. However, it is also possible to implement these rectifier elements 82₁, 82₂ as MOSFETs with integrated body diodes.

The operating principle of the rectifier circuit of FIG. 9 is as follows. When a positive input voltage Vin is applied between the first and second input terminals IN1, IN2 and when a load (not illustrated) is connected between the output terminals OUT1, OUT2, there is a conducting current path from the first input terminal IN1 via the third rectifier element 82₁, the first output terminal OUT1, the load, the second output terminal OUT2, and the second transistor device 10₂ to the second input terminal IN2. Referring to FIG. 9, the circuit arrangement may include a drive circuit 72 for providing drive signals DR₁, DR₂ to the first and second transistor devices 10₁, 10₂. According to one embodiment, the drive circuit 72 is operable to switch each of the first and second transistor devices 10₁, 10₂ on each time the body diode of the corresponding transistor device is forward biased. When the transistor device is switched on, the body diode is bypassed, so that losses occurring in the transistor device are reduced.

When a negative voltage is applied between the input terminals IN1, IN2, there is a conducting current path from the second input terminal IN2 via the fourth rectifier element 82₂, the first output terminal OUT1, the load Z, the second output terminal OUT2, and the first transistor device 10₁ to the first input terminal IN1.

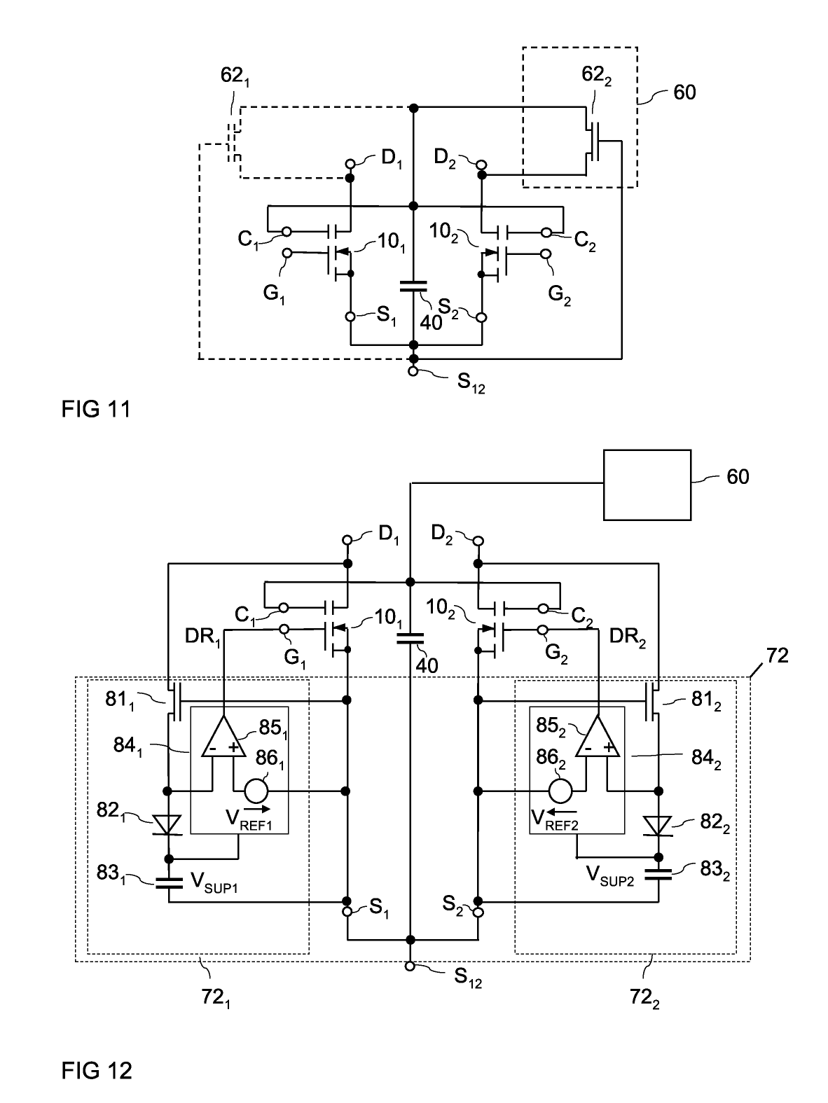

Referring to the explanation above, the charging circuit (biasing circuit) 60 can be implemented in different ways. Two embodiments for implementing the charging circuit 60 are explained next with reference to FIGS. 10 and 11.

FIG. 10 illustrates a first embodiment of the charging circuit 60. In this embodiment, the charging circuit 60 includes two rectifier elements 61₁, 61₂, such as diodes. Each of these rectifier elements 61₁, 61₂ is connected between the gate terminal G₁, G₂ of one transistor device 10₁, 10₂ and a capacitive storage element 40. In this charging circuit 60, the capacitive storage element 40 is charged each time the drive potential is applied to the gate terminal G₁, G₂ of one of the transistor devices 10₁, 10₂ and a voltage across the charge storage element 40.

FIG. 11 illustrates a charging circuit 60 according to a further embodiment. In this embodiment, the capacitive storage element 40 is connected to the second load terminal of at least one of the first and second transistor devices 10₁, 10₂ through a voltage limiting element. In this embodiment, the capacitive storage element 40 is charged as soon as a voltage is applied between that second load terminal coupled to the charge storage element 40 and the common first load terminal S₁₂. The voltage limiting element is configured to limit the voltage across the charge storage element 40 to a predefined voltage limit. In the embodiment of FIG. 11, the charge storage element 40 is connected to the second load terminal D₂ of the second transistor device 10₂. The voltage limiting element 62₂ is implemented as a depletion MOSFET or JFET that has its gate terminal connected to the common first load terminal S and that has its load path (drain-source path) connected between a second load terminal D₂ and a capacitive storage element 40.

According to a further embodiment (illustrated in dashed lines in FIG. 11) the capacitive storage element 40 is further connected to the second load terminal D₂ of the first transistor device 10₁ through a further voltage limiting element 62₁. This further voltage limiting element 62₁ may be implemented like the voltage limiting elements 62₂ as a depletion MOSFET or JFET.

FIG. 12 illustrates a circuit arrangement with first and second transistor devices 10₁, 10₂ that are both used as rectifier elements like in the rectifier circuit of FIG. 9. In FIG. 12, an embodiment of the drive circuit 72 that drives the first and second transistor devices 10₁, 10₂ is illustrated in detail. The drive circuit 72 is configured to detect the voltage across the load path of each transistor device 10₁, 10₂ and is configured to switch on one of the first and second transistor devices 10₁, 10₂ each time the load path voltage (drain-source-voltage) of this one transistor device 10₁, 10₂ is such that the body diode of the transistor device 10₁, 10₂ is forward biased. In an n-type transistor device the body diode is forward biased when the drain-source voltage is negative (that is, when the source-drain voltage is positive).

The drive circuit 72 of FIG. 12 includes two drive units 72₁, 72₂, namely a first drive unit 72₁ for driving the first transistor device 10₁, and a second drive unit 72₂ for driving the second transistor device 10₂. These two drive units 72₁, 72₂ are implemented identically. In these two drive units 72₁, 72₂ like features have like reference numbers, where the reference numbers of the first drive unit 72₁ additionally have a subscript index “1”, while the reference numbers of the second drive unit 72₂ have subscript index “2”. In the following, the implementation of one of the drive units 72₁, 72₂ is explained. In this connection, reference characters without index will be used. These reference characters relate to one of the drive units 72₁, 72₂. Further, reference character 10 denotes the transistor device driven by that drive unit, and reference characters D, S, G and C relate to this one transistor device 10.

Referring to FIG. 12, each drive unit 72₁, 72₂ includes a driver stage 84 with an output for providing the drive signal DR received at the gate terminal G of the corresponding transistor device 10. The driver stage 84 includes a first input coupled to the first load terminal S of the transistor device 10 and a second input coupled to the second load terminal D of the transistor device 10. Optionally, the first input of the driver stage 84 is coupled to the first load terminal S via a reference voltage source 86 providing a reference voltage V_{REF} (V_{REF}, in the first drive unit 72₁ and V_{REF2} in the second drive unit 72₂). The second input of the driver stage 84 is coupled to the second load terminal D via a voltage limiting element 81. The voltage limiting element 81 is configured to pass the electrical potential at the second load terminal D to the second input of the driver stage 84 as long as a voltage between the second and first load terminals D, S is below a predefined voltage threshold. When the voltage between the second and first load terminals D, S reaches the predefined voltage threshold, the voltage limiting element 81 prevents the electrical potential at the second input of the driver stage 84 from increasing further. Referring to FIG. 12, the voltage limiting element 81 can be implemented as a normally-on transistor, such as a depletion MOSFET or as a JFET, that has its gate terminal connected to the first load terminal S of the transistor device, that has its source terminal connected to the second load terminal D of the transistor device 10 and that has its drain terminal connected to the second input of the driver stage 84.

The driver stage 84 includes at least a comparator 85 that is configured to compare the electrical potential at the first and second inputs of the driver stage 84 and that drives the transistor device 10 dependent on these electrical potentials. In case an output signal provided by the comparator 85 is not suitable to drive the transistor 10, an optional amplifier (not illustrated) may receive the output signal from the comparator 85 and may drive the transistor device 10 dependent on the output signal.

Referring to FIG. 12, each drive unit 72₁, 72₂ further includes a capacitive storage element 83 connected between the voltage limiting element 81 and the first load terminal S of the transistor device 10. The capacitive storage element 83 provides a supply voltage V_{SUP} (V_{SUP1} in the first drive unit 72₁ and V_{SUP2} in the second drive unit 72₂). The supply voltage V_{SUP} is received by the driver stage 84 and supplies circuit elements in the driver stage 84, such as the reference voltage source 86 and the comparator 85. In order to prevent the capacitive storage element 83 from being discharged when the voltage limiting element 81 is conducting, a rectifier element 82, such as a diode, is connected between the voltage limiting element 81 and the capacitive storage element 83.

The operating principle of the drive units 72₁, 72₂ is explained in the following. For explanation purposes it is assumed that the transistor device 10 is an n-type normally-on transistor, such as an n-type depletion MOSFET or an n-type JFET. The gate terminal G of the normally-on transistor 81 is connected to the source terminal S of the transistor device 10, and the source terminal of the normally-on transistor 81 is connected to the drain terminal D. The normally-on transistor 81 has a negative threshold voltage or a threshold voltage of zero. In the following, the transistor device 10 will be referred to as “reverse biased” when a positive source-drain voltage (a negative drain-source voltage) is applied between the drain and source terminals D, S, and the transistor device 10 will be referred to as forward biased when a positive drain-source voltage is applied between the drain and source terminals D, S. The drive circuit 72 is configured to switch the transistor device 10 on when the transistor device 10 is reverse biased, and is configured to switch the transistor device 10 off when the transistor device 10 is forward biased. When the transistor device 10 is forward biased, the voltage limiting element 81 is switched on as long as a magnitude of the voltage at the source terminal of the transistor 81 is below the magnitude of the negative threshold voltage. The capacitive storage element 83 is charged when the transistor device 10 is forward biased and the voltage limiting element 81 is switched on.

When the transistor device 10 is forward biased, the electrical potential at the second input terminal is higher than the electrical potential at the first input terminal of the driver stage 84, so that the driver stage 84 keeps the transistor device 10 in the off-state.

When the transistor device 10 is reverse biased, the voltage limiting element 81 is switched on and passes through the electrical potential at the drain terminal D to the second input terminal of the driver stage 84. When the electrical potential at the source terminal S increases to the electrical potential at the drain terminal D plus the reference voltage V_{REF}, the driver stage 84 switches on the transistor device 10 (and bypasses the internal body diode which is not illustrated in FIG. 12). According to one embodiment, the reference voltage V_{REF} is below the forward-voltage of the body diode (not illustrated) of the transistor device 10. According to one embodiment, the reference voltage V_{REF} is about 0V.

The use of a transistor device with a drift control region as a rectifier element is not limited to circuit arrangements with two transistor devices 10₁, 10₂ that have the first load terminals S₁, S₂ connected and that include a common capacitive storage element 40.

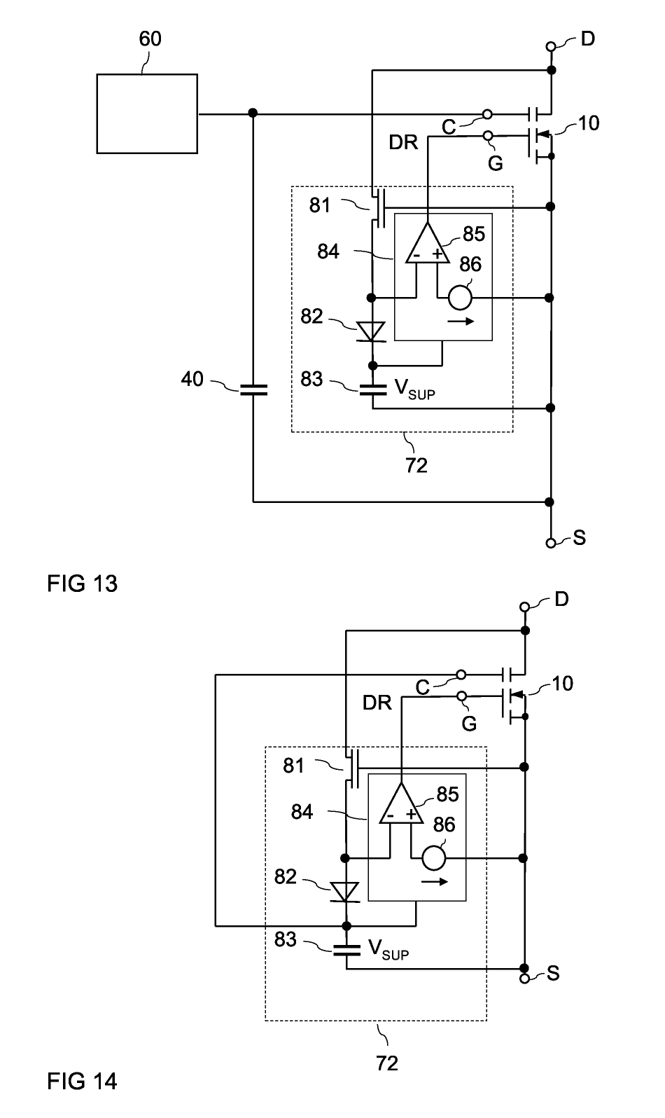

FIG. 13 illustrates a rectifier circuit with a transistor device 10 having a gate terminal G, a control terminal C and first and second load terminals D, S as explained before, and with a drive circuit 72 that is configured to switch on and off the transistor device 10 dependent on a voltage between the first and second load terminals D, S. The drive circuit 72 of FIG. 13 corresponds to one of the drive units 72₁, 72₂ explained with reference to FIG. 12. Like features are denoted with like reference characters in FIGS. 12 and 13.

In the rectifier circuit of FIG. 13 the capacitive storage element 40 is only assigned to one transistor device 10 and is connected between the control terminal C and the source terminal S. A charging circuit 60 is connected to the capacitive storage element 40. This charging circuit 60 may be implemented in accordance with one of the embodiments explained with reference to FIGS. 10 and 11. When the charging circuit 60 of FIG. 13 is implemented as explained with reference to FIG. 10, only one rectifier element, namely a rectifier element connected between the gate terminal G and the control terminal C is required. When the charging circuit 60 is implemented as explained with reference to FIG. 11, one normally-on transistor is required, namely a normally-on transistor having its load path connected between the control terminal C and the drain terminal D and having its control terminal (gate terminal) connected to the source terminal S of the transistor device 10.

FIG. 14 illustrates a modification of the rectifier circuit of FIG. 13. In the rectifier circuit of FIG. 13, the charge storage element 83 of the drive circuit 72 is connected to the control terminal C of the transistor device 10. In this rectifier circuit, the charge storage element 83 provides the supply voltage V_{SUP} to the driver stage 84. Further, the charge storage element 83 has the functionality of the capacitive storage element 40 of FIG. 13 and provides the charge to the drift control region required to generate a conducting channel in the drift region when the transistor device 10 is in the on-state. The capacitive storage element 83 is charged through the voltage limiting element 81 implemented as a normally-on transistor.

The drive circuit 72 explained before that operates the transistor device 10 as a rectifier element is not limited to be used in connection with a transistor device 10 having a control terminal C coupled to a drift control region of the transistor device. This drive circuit 72 could also be used in connection with any other type of conventional transistor device, in particular a MOSFET with an integrated body diode, as well.

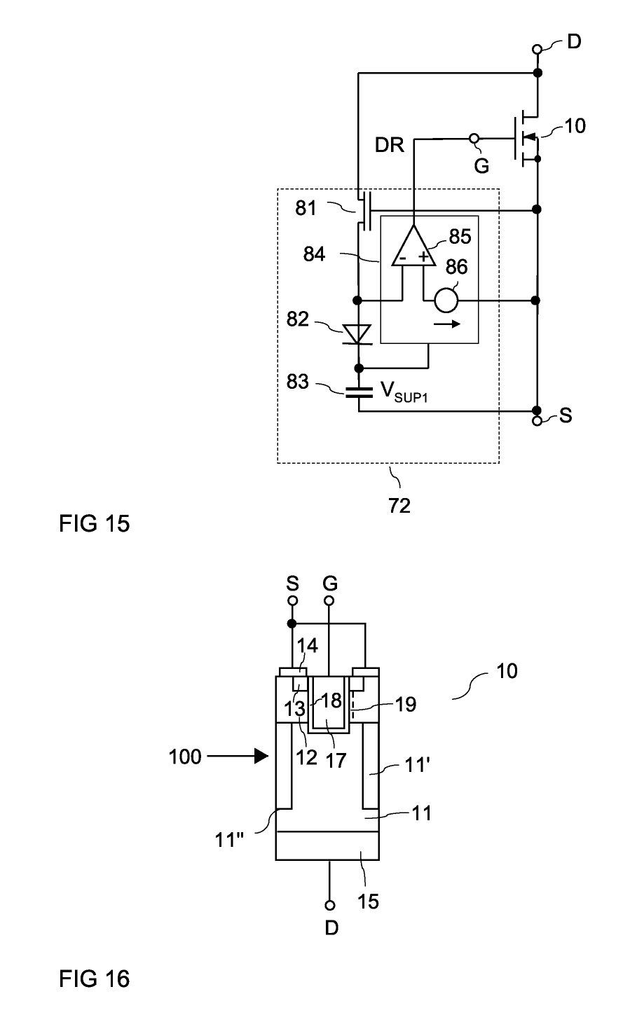

FIG. 15 illustrates a rectifier circuit that includes the drive circuit 72 explained before and that includes a conventional MOSFET as the transistor device 10. The drive circuit 72 is connected to the drain, source and gate terminals, D, S, G of the transistor device 10 as explained before. According to one embodiment, the transistor device 10 is implemented as a superjunction transistor. A superjunction transistor is a transistor with a drift region and with compensation regions located in the drift region. The compensation regions and the drift region form pn-junctions. Further, the compensation regions are electrically connected to the source terminal S of the transistor device 10.

Superjunction transistors are commonly known. However, just for illustration purposes, a vertical cross sectional view of a section of a superjunction transistor, specifically of a superjunction MOSFET, according to one embodiment is schematically illustrated in FIG. 16. The transistor 10 of FIG. 16 is implemented as a vertical MOSFET and includes a drift region 11, a source 13 coupled to a source terminal S, a body region 12, and a drain region 15 coupled to a drain terminal D in a semiconductor body 100. The body region 12 separates the source region 13 from the drift region 11, and the drift region 11 is arranged between the body region 12 and the drain region 15. A gate electrode 17 coupled to a gate terminal G is adjacent the body region 12 and dielectrically insulated from the body region 12 by a gate dielectric 18. Optionally, a channel region 19 extends from the source region 13 to the drift region 11 along the gate dielectric 18. The MOSFET may include plurality of identical transistor cells, with each transistor cell including a source region 12, a body region 12, a drift region 11, a drain region 15, a gate electrode 17 and a gate dielectric 18, where two or more transistor cells may share one drift region 11 and one drain region 15, and where two or more transistor cells may share one gate electrode 17 and/or one body region 12. In the embodiment of FIG. 16, one transistor cell is shown

The MOSFET may be implemented as an n-type MOSFET or as a p-type MOSFET. In an n-type MOSFET, the source region 13, the drift region 11, and the drain region 15 are n-doped, while the body region 12 is p-doped. In a p-type MOSFET, the doping types of the individual device regions are complementary to the doping types in an n-type MOSFET. Further, the MOSFET may be implemented as an enhancement MOSFET or as a depletion MOSFET. In an enhancement MOSFET, the body region 12 adjoins the gate dielectric 18, while in a depletion MOSFET a channel region of the same doping type as the source and drift regions 13, 11 is arranged between the gate dielectric 18 and the body region 12. Concerning the doping concentrations of the individual device regions reference is made to the description of FIG. 2, which applies to the MOSFET of FIG. 16 accordingly.

The MOSFET of FIG. 16 is implemented as a vertical MOSFET with a trench electrode. However, this is just for illustration purposes. The MOSFET could be implemented with a different device topology, e.g., with a planar gate electrode, or as a lateral transistor device as well.

Referring to FIG. 16, the superjunction MOSFET includes at least one compensation region 11′ of a doping type complementary to the doping type of the drift region 11. The at least one compensation region 11′ is electrically coupled to the source terminal S that is electrically connected to the source region 13 and the body region 12. In the embodiment of FIG. 16, the at least one compensation region 11′ adjoins the body region 12 and is electrically coupled to the source terminal S via the body region 12. A pn-junction is formed between the compensation region 11′ and the drift region 11, as well as between the body region 12 and the drift region 11.

The operating principle of the superjunction MOSFET of FIG. 16 is as follows. When the MOSFET is switched off (blocks) and the MOSFET is forward biased (that is, when a voltage is applied between the drain and source terminals D, S that reverse biases the pn-junction between the body region 12 and the drift region 11), the pn-junction between the compensation region 11′ and the drift region 11 is also reverse biased. This causes a depletion region to expand in the drift region 11. By virtue of the at least one compensation region 11′ there is a compensation effect such that doping charges in the at least one compensation region 11′ compensate complementary doping charges in the drift region 11. Thus, the drift region 11 in a superjunction device can be implemented with a higher doping concentration than a conventional MOSFET, resulting in a lower on-resistance.

The body diode of the MOSFET of FIG. 16 is formed by the pn-junctions between the body region 12 and the drift region 11 and between the compensation regions 11′ and the drift region. When the MOSFET is reverse biased (that is, when a voltage is applied between the drain and source terminals D, S that reverse biases these pn-junctions) the body diode is conducting. The voltage drop between the drain and source terminals D, S basically corresponds to forward voltage of the pn-junction (which is about 0.7V in silicon) plus the voltage drop across the drift region 11. The voltage drop across the drift region 11 is dependent on the load current flowing through the reverse biased MOSFET and the length of the drift region 11 between the pn-junction and the drain region 15.

In a superjunction MOSFET, such as the superjunction MOSFET of FIG. 16, one end 11″ (that will be referred to as lower end in the following) of the compensation region 11′ is closer to the drain region 15 than the body region 12. As the MOSFET is reverse biased, the pn-junction between the lower end 11″ of the compensation region 11′ and the drift region 11 starts to conduct before pn-junctions that are more distant to the drain region 15, such as the pn-junction between the body region 12 and the drift region, 11 may start to conduct. The voltage drop is limited to a voltage corresponding to the forward voltage of the pn-junction plus the voltage drop across that section of the drift region 11 that is between the lower end 11″ of the compensation region 11′ and the drain region 15. Since the length of the drift region 11 between the lower end 11″ of the compensation region 11′ is, usually, significantly lower than the overall length of the drift region 11 (which is the distance between the body region 12 and the drain region 15), the voltage drop across a superjunction MOSFET that is reverse biased and that is switched on (by applying a suitable drive potential to the gate terminal G) is limited to the voltage drop of the pn-junction between the lower end 11″ of the compensation region 11′ and the drift region 11. In a conventional MOSFET that is reverse biased and turned on, the pn-junction between the body region and the drift region is shortened by the channel region in the body region. Therefore the drift region of a conventional MOSFET will not be flooded with electrons and holes in the case of high surge currents in contrast to a superjunction MOSFET. Thus, at high surge currents, the power dissipated in a superjunction MOSFET that is reverse biased (and that has been switched on) is much lower than the power dissipated in a comparable conventional MOSFET.

Thus, a superjunction MOSFET is more robust in terms of high load currents flowing in the reverse direction than a conventional MOSFET.

Although various exemplary embodiments of the invention have been disclosed, it will be apparent to those skilled in the art that various changes and modifications can be made which will achieve some of the advantages of the invention without departing from the spirit and scope of the invention. It will be obvious to those reasonably skilled in the art that other components performing the same functions may be suitably substituted. It should be mentioned that features explained with reference to a specific figure may be combined with features of other figures, even in those cases in which this has not explicitly been mentioned. Further, the methods of the invention may be achieved in either all software implementations, using the appropriate processor instructions, or in hybrid implementations that utilize a combination of hardware logic and software logic to achieve the same results. Such modifications to the inventive concept are intended to be covered by the appended claims.

Spatially relative terms such as “under”, “below”, “lower”, “over”, “upper” and the like, are used for ease of description to explain the positioning of one element relative to a second element. These terms are intended to encompass different orientations of the device in addition to different orientations than those depicted in the figures. Further, terms such as “first”, “second”, and the like, are also used to describe various elements, regions, sections, etc. and are also not intended to be limiting. Like terms refer to like elements throughout the description.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

It is to be understood that the features of the various embodiments described herein may be combined with each other, unless specifically noted otherwise.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A circuit arrangement, comprising:
a first transistor device and a second transistor device, each comprising a first load terminal, a second load terminal, a gate terminal, and a control terminal, wherein the first load terminals are electrically connected, and wherein the control terminals are electrically connected; and
a capacitive storage element connected between the first load terminals and the control terminals.

2. The circuit arrangement of claim 1, wherein the first transistor device and the second transistor device are integrated in one common semiconductor body.

3. The circuit arrangement of claim 2, wherein the capacitive storage element is integrated in the one semiconductor body.

4. The circuit arrangement of claim 3, wherein the capacitive storage element comprises a plurality of storage cells connected in parallel.

5. The circuit arrangement of claim 1, wherein:
the first transistor device is integrated in a first semiconductor body; and
the second transistor device is integrated in a second semiconductor body.

6. The circuit arrangement of claim 5, wherein:
the capacitive storage element comprises a plurality of storage cells connected in parallel;
at least one of the storage cells is integrated in the first semiconductor body; and
wherein at least one of the storage cells is integrated in the second semiconductor body.

7. The circuit arrangement of claim 1, further comprising a charging circuit coupled to the control terminals.

8. The circuit arrangement of claim 7, wherein the charging circuit further comprises at least one rectifier element connected between the gate terminal of one of the first and second transistor devices and the control terminals.

9. The circuit arrangement of claim 8, wherein the charging circuit further comprises:
a first rectifier element connected between the gate terminal of the first transistor device and the control terminals; and
a second rectifier element connected between the gate terminal of the second transistor device and the control terminals.

10. The circuit arrangement of claim 7, wherein the charging circuit is operable to couple the capacitive storage element to the second load terminal of at least one of the first and second transistor devices, and to limit a voltage across the capacitive storage element.

11. The circuit arrangement of claim 10, wherein the charging circuit comprises at least one depletion transistor having a load path and a control terminal, the load path coupled between the second load terminal of one of the first and second transistor devices and the control terminals, the control terminal of the at least one depletion transistor being coupled to the first load terminal of the one of the first and second transistor devices.

12. The circuit arrangement of claim 10, wherein the charging circuit comprises:
a first depletion transistor having a load path and a control terminal, the load path of the first depletion transistor coupled between the second load terminal of the first transistor device and the control terminals, the control terminal of the first depletion transistor coupled to the first load terminal of the first transistor device; and
a second depletion transistor having a load path and a control terminal, the load path of the second depletion transistor coupled between the second load terminal of the second transistor device and the control terminals, the control terminal of the second depletion transistor coupled to the first load terminal of the second transistor device.

13. The circuit arrangement of claim 1, wherein each of the first and second transistor devices comprises:
a source region coupled to the first load terminal;
a drain region coupled to the second load terminal;
a body region and a drift region, the drift region arranged between the drain region and the body region;
a gate electrode adjacent the body region, dielectrically insulated from the body region and coupled to the gate terminal; and
a drift control region adjacent the drift region, dielectrically insulated from the drift region and coupled to the control terminal.

14. The circuit arrangement of claim 1, further comprising:
a first switching element coupled between the second load terminal of the first transistor device and a terminal for a supply potential; and
a second switching element coupled between the second load terminal of the second transistor device and a terminal for a supply potential.

15. The circuit arrangement of claim 1, further comprising:
a first rectifier element coupled between the second load terminal of the first transistor device and a first output terminal;
a second rectifier element coupled between the second load terminal of the second transistor device and the first output terminal;
a second output terminal coupled to the first load terminals of the transistor devices;
a first input terminal coupled to a circuit node common to the first transistor device and the first rectifier element;
a second input terminal coupled to a circuit node common to the second transistor device and the second rectifier element; and
a drive circuit operable to drive one of the first and the second transistor devices in an on-state dependent on a voltage between the input terminals.

16. A rectifier circuit, comprising:
a transistor device comprising a first load terminal, a second load terminal, a gate terminal, and a control terminal, the control terminal coupled to a drift control region, the drift control region being dielectrically insulated from a drift region by a drift control region dielectric; and
a drive circuit configured to detect a polarity of a voltage between the first load terminal and the second load terminal and generate a drive signal received at the gate terminal of the transistor device dependent on the detected polarity.

17. The rectifier circuit of claim 16, wherein the transistor device further comprises an internal diode coupled between the first load terminal and the second load terminal.

18. The rectifier circuit of claim 16, wherein the drive circuit further comprises a driver stage with an output coupled to the gate terminal of the transistor device, a first input coupled to the first load terminal of the transistor device, and a second input coupled to the second load terminal of the transistor device via a voltage limiting element.

19. The rectifier circuit of claim 18, wherein the voltage limiting element comprises a normally-on transistor with a load path connected between the second input of the driver stage and the second load terminal of the transistor device, and with a control terminal coupled to the first load terminal of the transistor device.

20. The rectifier circuit of claim 18, wherein the driver stage further comprises a comparator with a first input coupled to the first input of the driver stage via a reference voltage source and with a second input coupled to the second input of the driver stage.

21. The rectifier circuit of claim 18, further comprising a capacitive storage element coupled between the voltage limiting element and the first load terminal of the transistor device and operable to provide a supply voltage to the driver stage.

22. The rectifier circuit of claim 21, wherein the capacitive storage element is further coupled to the control terminal of the transistor device.

23. A rectifier circuit, comprising:
a transistor device comprising a first load terminal, a second load terminal, and a gate terminal; and
a drive circuit configured to detect a polarity of a voltage between the first load terminal and the second load terminal and generate a drive signal received at the gate terminal of the transistor device dependent on the detected polarity, the drive circuit comprising a driver stage with an output coupled to the gate terminal of the transistor device, a first input coupled to the first load terminal of the transistor device, and a second input coupled to the second load terminal of the transistor device via a voltage limiting element.

24. The rectifier circuit of claim 23, wherein the voltage limiting element comprises a normally-on transistor with a load path connected between the second input of the driver stage and the second load terminal of the transistor device, and with a control terminal coupled to the first load terminal of the transistor device.

25. The rectifier circuit of claim 23, wherein the driver stage further comprises a comparator with a first input coupled to the first input of the driver stage via a reference voltage source and with a second input coupled to the second input of the driver stage.

26. The rectifier circuit of claim 23, wherein the transistor device is implemented as a superjunction MOSFET.
